(19) United States
(12) Patent Application Publication
(10) Pub. No.: US 2024/0379823 A1
(43) Pub. Date: Nov. 14, 2024

(54) BEVEL STRUCTURE AND ITS MANUFACTURING METHOD, LDMOS STRUCTURE AND ITS MANUFACTURING METHOD

(71) Applicant: Silergy Semiconductor Technology (Hangzhou) LTD, Hangzhou (CN)

(72) Inventor: Huan Wang, Hangzhou (CN)

(21) Appl. No.: 18/655,527

(22) Filed: May 6, 2024

(30) Foreign Application Priority Data
May 11, 2023 (CN) 202310532896.7

(51) Int. Cl. H01L 29/66; H01L 21/311; H01L 29/78

(52) U.S. Cl. CPC H01L 29/66681; H01L 21/31116; H01L 29/7816

(57) ABSTRACT

A method of making a bevel structure can include: forming an insulating layer on a substrate; forming a first photoresist layer on the insulating layer; performing an exposure and development process on the first photoresist layer to form a second photoresist layer; using the second photoresist layer as a mask to perform a first etching process from an upper surface of the exposed insulating layer until the upper surface of the substrate is exposed; removing part of a first side of the second photoresist layer to continuously expose the upper surface of the insulating layer; using a retained portion of the second photoresist layer as a mask to perform a second etching process from the upper surface of the exposed insulating layer to inside the insulation layer to form a stair-step insulating layer with decreasing length; and wet etching the stair-step insulating layer to form a smooth bevel structure.

### RELATED APPLICATIONS

This application claims the benefit of Chinese Patent Application No. 202310532896.7, filed on May 11, 2023, which is incorporated herein by reference in its entirety.

### FIELD OF THE INVENTION

The present invention generally relates to the field of semiconductor technology, and more particularly to bevel and LDMOS structures, and methods of making bevel and LDMOS structures.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIGS. 1A-1G are structural diagrams of steps of an example manufacturing method of a bevel structure, in accordance with embodiments of the present invention.

FIG. 2 is a cross-sectional diagram of the example bevel structure applied to a LDMOS device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

In making power devices (e.g., laterally-diffused metal-oxide-semiconductor [LDMOS] devices), and particularly using a local oxidation of silicon (LOCOS) process to form the field oxide layer, there are a number of different devices/designs on the junction between the high-voltage field oxide isolation structure and the shallow trench isolation structure (STI). Because of the particularity of the LOCOS process, it can be easy to form upward sharp corners at the junction. After the process has completed, the sharp corners at the junction can form charge accumulation, which may reduce the actual thickness of the field oxide layer between the substrate and the polysilicon layer. This can result in the breakdown of the field oxide layer at the junction and reliability issues with gate oxide integrity (GOI).

In one example LDMOS high-voltage oxide layer process of an 0.18 um power device, a high-temperature oxide layer may first be deposited on a silicon substrate. Then, the structure may use exposure lithography, and an area for etching may define the high-voltage oxide layer. Dry etching can then occur, and photoresist may be removed to form the high-voltage oxide layer area. The side of the high-voltage oxide layer formed by this approach can be perpendicular to the silicon substrate. Also, the tip of the vertical surface of the high-voltage oxide layer can be prone to charge accumulation, which may result in a decrease in breakdown voltage.

In particular embodiments, a method for forming a bevel structure can include forming an insulating layer on a substrate, and a first photoresist layer on the insulating layer. The method can also include performing an exposure and development process on the first photoresist layer to form a second photoresist layer, where an upper surface of part of the insulating layer to be etched may be exposed by the second photoresist layer. The method can also include performing a first etching process from an upper surface of the exposed insulation layer by using the second photoresist layer as a mask until the upper surface of the substrate is exposed. The method can also include removing part of a first side of the second photoresist layer to continuously expose part of the upper surface of the insulating layer. The method can also include using the second photoresist layer retained in the previous step as the mask to performing a second etching process from the upper surface of the exposed insulating layer to inside the insulation layer to form a stair-step insulating layer with decreasing length in turn. The method can also include wet etching the stair-step insulating layer to form a smooth bevel. For example, multiples of the previous two steps can be performed prior to this step.

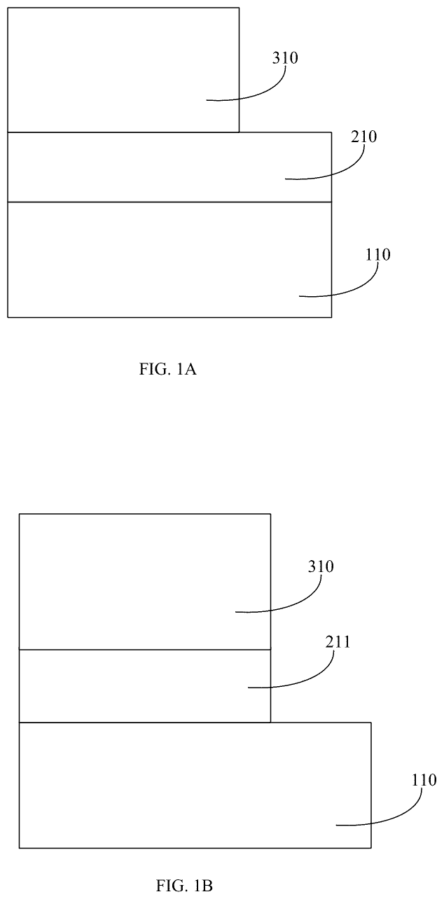

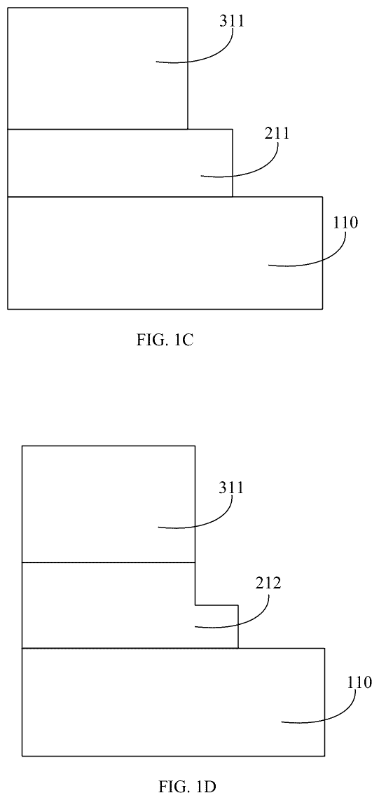

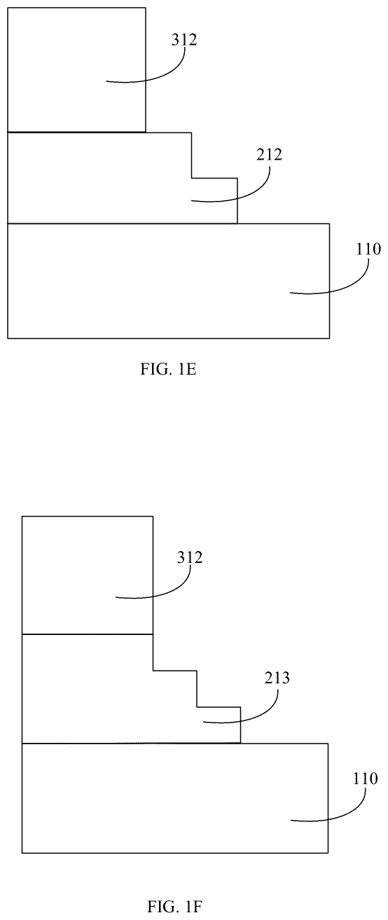

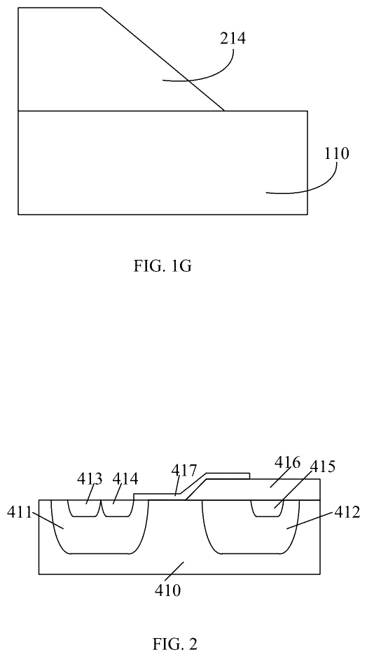

Referring now to FIGS. 1A-1G, shown are structural diagrams of steps of an example manufacturing method of a bevel structure, in accordance with embodiments of the present invention. In FIG. 1A, insulating layer 210 can be formed on semiconductor substrate 110, and a photoresist layer may be formed on insulating layer 210. A selective exposure and development process can be performed on the photoresist layer to form patterned photoresist layer 310. For example, an upper surface of insulating layer 210 to be etched may be exposed by patterned photoresist layer 310.

In particular embodiments, the material of semiconductor substrate 110 can be monocrystalline silicon (Si), monocrystalline germanium (Ge), silicon germanium (GeSi), or silicon carbide (SiC), or other suitable materials, such as III-V compounds (e.g., gallium arsenide). Insulating layer 210 can be silicon oxide, silicon nitride, or silicon oxynitride, etc., The thickness of insulating layer 210 can be configured as from about 200 Å to about 2000 Å. Also, patterned photoresist layer 310 can be formed by photolithography technology.

In FIG. 1B, patterned photoresist layer 310 may be utilized as a mask to perform a first etching process on exposed insulating layer 210. The first etching process can be performed to etch from the upper surface of insulating layer 210 until the upper surface of substrate 110 is exposed to form insulating layer 211. The first etching process can be configured as dry etching process, such as, e.g., ion milling etching, plasma etching, reactive ion etching, laser ablation, or selective wet etching using an etchant solution.

In FIG. 1C, patterned photoresist layer 310 may be performed an ashing treatment, and part of patterned photoresist layer 310 can be removed to form photoresist layer 311. Photoresist layer 311 can continue to expose part of an upper surface of insulating layer 211 to be etched. For example, a portion of the thickness on the first side of photoresist layer 310 can be removed to expose the upper surface of second insulation layer 211, where the etched part of insulating layer 210 and the first side of the first photoresist layer are located on the same side.

In FIG. 1D, photoresist layer 311 can be used as a mask to perform a second etching process on insulating layer 211. The second etching process may be performed to etch from the upper surface of insulating layer 211 to the interior of insulating layer 211 to form a stair-step insulating layer 212. For example, the thickness of the etched part of insulating layer 211 in this step can be half of the thickness of the insulating layer 211. The second etching process can be configured as dry etching process, such as, e.g., ion milling etching, plasma etching, reactive ion etching, laser ablation, or selective wet etching using an etchant solution.

In FIG. 1E, repeating the step in FIG. 1C and continuing to perform an ashing treatment on photoresist layer 311, part of photoresist layer 311 may be removed to form photoresist layer 312, and an upper surface of part of stair-step insulating layer 212 can be exposed by photoresist layer 312.

In FIG. 1F, repeating the step in FIG. 1D, a third etching process can be performed on stair-step insulating layer 212 by using photoresist layer 312 as a mask. The third etching process may be performed to etch from the upper surface of stair-step insulating layer 212 to the interior of stair-step insulating layer 212 to form stair-step insulating layer 213. For example, the thickness of the etched part of stair-step insulating layer 212 here can be less than the thickness of each stair of stair-step insulation layer 212.

The steps in FIGS. 1C and 1D can be repeated in order to obtain the desired stairs. For example, the amount of stairs of the stair-step insulating layer may be consistent with (e.g., the same as) the amount of the dry etching processes. In particular embodiments, the stair-step insulating layer may include, e.g., 5-10 stairs. For example, the height of each stair of stair-step insulating layer can be the same, and the length difference between each upper and lower of adjacent stairs may be the same. It should be noted that in the steps of etching processes except the first etching process, the thickness of the insulating layer to be etched away in each of the steps can be less than the thickness of the thinnest stair of the stair-step insulating layer formed by the previous steps.

In FIG. 1G, photoresist layer 312 may be removed by performing an ashing treatment, and a wet etching process can be performed on stepped insulating layer 213. The wet etching can be an isotropic wet etching, and the sharp corners of the stairs can be corroded off to form a smooth bevel insulating layer 214.

It should be noted that the above steps in FIGS. 1E and 1F can be omitted in some cases, or repeated multiple times, as long as the ideal angle and number is obtained. For example, the angle of the formed bevel structure can be changed by changing the number of the dry etching processes discussed above, or by changing the thickness of the photoresist layer to be removed each step. For example, the angle of the formed bevel structure may not be less than 45° and not greater than 60°.

In particular embodiments, the solution used for wet etching can, e.g., be hydrofluoric acid. By controlling the time of wet etching, the exposure degree of sharp corners of each step can be controlled. In other examples, other solutions that eliminate oxides can also be used, such as buffered oxide etch (BOE), which has relatively high selectivity for oxides. This is composed of hydrofluoric acid (e.g., 49%) mixed with water or ammonium fluoride mixed with water, or different ratios of hydrofluoric acid (e.g., 1:10, 1:100, etc.).

The bevel structure formed in particular embodiments may be used as a high-voltage oxide layer in semiconductor devices, such as in MOS devices, located between the gate conductor and the drain region, in order to withstand the high voltage of the drain region. The bevel structure can reduce accumulation of the drain region, thus making the electric field distribution more uniform, and improving the breakdown voltage of the device.

As shown in FIG. 1G, bevel structure 214 can be formed according to the above method, and the material of the bevel structure can be, e.g., silicon oxide, silicon nitride, or silicon oxynitride, etc., The thickness of bevel structure 214 can be configured from about 200 Å to about 2000 Å, and the angle of bevel structure may not be less than 45° and not greater than 60°. For example, the bevel structure can be applied in the semiconductor device as a high-voltage oxide layer, in order to improve the breakdown voltage of the semiconductor device.

Referring now to FIG. 2, shown is a cross-sectional diagram of the example bevel structure applied to a LDMOS device, in accordance with embodiments of the present invention. In this particular example, the LDMOS structure can include substrate 410, drift region 412, and body region 411 located in substrate 410, source region 414 and body contact region 413 located in body region 411, drain region 415 located in drift region 412, and gate conductor 417 and high-voltage oxide layer 416 located on an upper surface of the substrate. For example, the portion of gate conductor 417 extending to high-voltage oxide layer 416 can be configured as the field plate of the LDMOS. The high-voltage oxide layer can be located between the field plate and the substrate, and starting from gate conductor 417 and at least extending to drain region 415, in order to withstand the high voltage of the drain region.

High-voltage oxide layer 416 can reduce accumulation of the drain region, thereby making the electric field distribution more uniform, and improving the breakdown voltage of the device. High-voltage oxide layer 416 in the LDMOS structure can be a bevel structure formed by methods of particular embodiments, as discussed above. Of course, the bevel structure can also be applied to other semiconductor devices (e.g., diodes, transistors, or other types of MOS structures), and may have the same function as in the LDMOS structure in particular embodiments, which can withstand high voltages in order to improve the breakdown voltage of the device.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of making a bevel structure, the method comprising:
a) forming an insulating layer on a substrate;
b) forming a first photoresist layer on the insulating layer;
c) performing an exposure and development process on the first photoresist layer to form a second photoresist layer, wherein an upper surface of part of the insulating layer to be etched is exposed by the second photoresist layer expose;
d) using the second photoresist layer as a mask to perform a first etching process from an upper surface of the exposed insulating layer until the upper surface of the substrate is exposed;
e) removing part of a first side of the second photoresist layer to continuously expose the upper surface of the insulating layer;
f) using a retained portion of the second photoresist layer as a mask to perform a second etching process from the upper surface of the exposed insulating layer to inside the insulation layer to form a stair-step insulating layer with decreasing length; and
g) wet etching the stair-step insulating layer to form a smooth bevel structure.

2. The method of claim 1, further comprising, before the wet etching, repeating one or more previous steps at least once to form a plurality of stair structures.

3. The method of claim 2, wherein the first and second etching processes each comprise a dry etching process.

4. The method of claim 3, wherein in the steps of etching processes other than the first etching process, the thickness of the insulating layer to be etched away in each step is less than a thickness of a thinnest stair of the stair-step insulating layer formed by previous steps.

5. The method of claim 3, wherein an angle of the bevel structure is changed by changing the number of the dry etching processes.

6. The method of claim 1, wherein an angle of the bevel structure is changed by changing the thickness of the photoresist layer to be removed each step.

7. The method of claim 1, wherein an angle of the bevel structure is not less than 45° and not greater than 60°.

8. The method of claim 1, wherein the thickness of the insulating layer is configured as from 200 Å to 2000 Å.

9. The method of claim 1, wherein part of a first side of the second photoresist layer is removed by an ashing process.

10. The method of claim 1, wherein a height of each stair of stair-step insulating layer is the same.

11. The method of claim 1, wherein a length difference between each upper and lower adjacent stairs is the same.

12. The method of claim 3, wherein a number of stairs of the stair-step insulating layer is the same as a number of the dry etching processes.

13. The method of claim 1, wherein the stair-step insulating layer comprises 5 to 10 stairs.

14. The method of claim 1, wherein the bevel structure is configured as a high-voltage oxide layer in a semiconductor device.

15. An apparatus, comprising the bevel structure formed by the method of claim 1.

16. An LDMOS structure, comprises the bevel structure of claim 15, and further comprising:
a) a drift region and a body region located in a substrate;
b) a drain region located in the drift region and a source region located in the body region;
c) a gate structure located on a upper surface of the substrate; and
d) wherein the bevel structure is located between the gate structure and the drain region, and is used to withstand the high voltage of the drain region.

17. A method of making an LDMOS structure, the method comprising forming the bevel structure of claim 1, and further comprising:
a) forming a drift region and a body region in the substrate;
b) forming a drain region in the drift region and a source region in the body region;
c) forming a gate structure on an upper surface of the substrate; and
d) wherein the bevel structure is located between the gate structure and the drain region, and is used to withstand the high voltage of the drain region.
